(19) United States
(12) Patent Application Publication
(10) Pub. No.: US 2008/0122122 A1
(43) Pub. Date: May 29, 2008

(54) Semiconductor package with encapsulant delamination-reducing structure and method of making the package

(76) Inventors: Weng Fei Wong, Penang (MY); Fu Mauh Wong, Penang (MY)

Correspondence Address: Kathy Manke;Avago Technologies Limited, 4380 Ziegler Road, Fort Collins, CO, 80525, US

(21) Appl. No.: 11/594,603

(22) Filed: Nov. 8, 2006

(51) Int. Cl. H01L 23/31; H01L 21/71

(52) U.S. Cl. 257/787; 438/127; 257/E23.124; 257/E21.536

(57) ABSTRACT

A semiconductor package and method of making the package uses at least one encapsulant delamination-reducing structure positioned on an upper major surface of a semiconductor chip to provide a structural interface between the semiconductor chip and an encapsulant formed over the semiconductor chip.

### BACKGROUND OF THE INVENTION

Some optoelectronic packages use an encapsulating material to encapsulate one or more semiconductor chips mounted on a substrate. The resulting encapsulant protects the mounted semiconductor chips. As an example, the semiconductor chips in the optoelectronic packages may include light emitting semiconductor dies and integrated circuit dies with photosensors.

A common concern in these encapsulated optoelectronic packages is delamination of the encapsulant and the semiconductor chip(s). Encapsulant delamination in optoelectronic packages can significantly degrade the performance of these packages. The encapsulant delamination may also lead to package crack, which can have more severe consequences, including complete package failure. Encapsulant delamination and package crack formation usually occur during solder reflow when the package is subjected to thermal and moisture expansion.

Current methods to reduce the encapsulant delamination problem in encapsulated optoelectronic packages include using encapsulating material with lower coefficient of thermal expansion (CTE) and modulus of elasticity, which reduces the thermal mismatch between the encapsulant and the semiconductor chip(s). Using encapsulating material with low moisture absorption is also preferable to reduce moisture content of the encapsulant prior to solder reflow.

Another method to reduce the encapsulant delamination problem in encapsulated optoelectronic packages involves improving the adhesion between the encapsulant and the semiconductor chip(s) by adding adhesion promoter to the encapsulating material.

Although the above methods to reduce the encapsulant delamination problem in encapsulated optoelectronic packages work well for their intended purpose, there is a need for a semiconductor package, such as an optoelectronic package, that can further reduce the encapsulant delamination problem.

### SUMMARY OF THE INVENTION

A semiconductor package and method of making the package uses at least one encapsulant delamination-reducing structure positioned on an upper major surface of a semiconductor chip to provide a structural interface between the semiconductor chip and an encapsulant formed over the semiconductor chip. The encapsulant delamination-reducing structure reduces the possibility of delamination and/or cracking between the semiconductor chip and the encapsulant, especially during solder reflow.

A semiconductor package in accordance with an embodiment of the invention comprises a substrate, a semiconductor chip, an encapsulant and at least one encapsulant delamination-reducing structure. The substrate has a surface over which the semiconductor chip is positioned. The semiconductor chip has an upper major surface that faces away from the surface of the substrate. The encapsulant is positioned to encapsulate the semiconductor chip. The at least one encapsulant delamination-reducing structure is positioned on the upper major surface of the semiconductor chip to provide a structural interface between the semiconductor chip and the encapsulant.

A method of making a semiconductor package in accordance with an embodiment of the invention comprises providing a substrate and a semiconductor chip of the semiconductor package, mounting the semiconductor chip onto a surface of the substrate such that an upper major surface of the semiconductor chip faces away from the surface of the substrate, forming at least one encapsulant delamination-reducing structure on the upper major surface of the semiconductor chip, and forming an encapsulant over the semiconductor chip using an encapsulating material to encapsulate the semiconductor chip and the at least one encapsulant delamination-reducing structure. The at least one encapsulant delamination-reducing structure provides a structural interface between the semiconductor chip and the encapsulant.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a cross-sectional view of a semiconductor package with dummy studs in accordance with an embodiment of the invention.

FIG. 2A is a top view of a semiconductor chip of the semiconductor package of FIG. 1, which shows an arrangement of dummy studs formed on the semiconductor chip in accordance with an embodiment of the invention.

FIG. 2B is a top view of the semiconductor chip of the semiconductor package, which shows another arrangement of dummy studs formed on the semiconductor chip in accordance with another embodiment of the invention.

FIG. 3 is a cross-sectional view of the semiconductor package with dummy pillars in accordance with another embodiment of the invention.

FIG. 4 is a cross-sectional view of the semiconductor package with dummy blocks in accordance with another embodiment of the invention.

FIG. 5A is a top view of the semiconductor chip of the semiconductor package, which shows an arrangement of dummy blocks attached to the semiconductor chip in accordance with an embodiment of the invention.

FIG. 5B is a top view of the semiconductor chip of the semiconductor package, which shows an arrangement of a single large dummy block attached to the semiconductor chip in accordance with an embodiment of the invention.

FIG. 6 is a process flow diagram of a method of making a semiconductor package in accordance with an embodiment of the invention.

### DETAILED DESCRIPTION

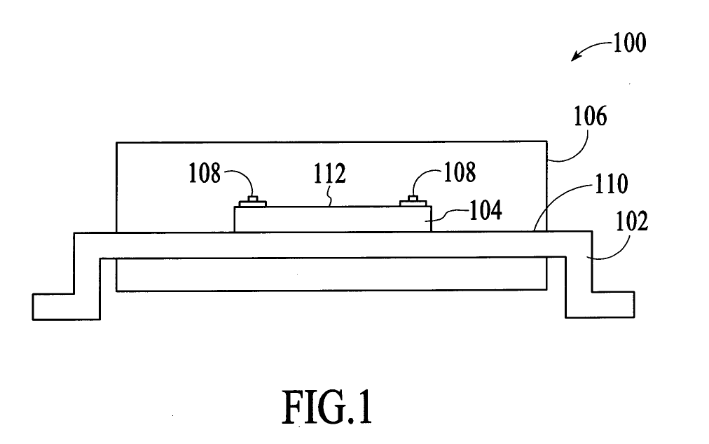

With reference to FIG. 1, a semiconductor package 100 in accordance with an embodiment of the invention is described. FIG. 1 is a cross-sectional view of the semiconductor package 100. As shown in FIG. 1, the semiconductor package 100 includes a substrate 102, a semiconductor chip 104 and an encapsulant 106. The semiconductor chip 104 is encapsulated by the encapsulant 106, which protects the semiconductor chip. As described in more detail below, the semiconductor package 100 further includes one or more encapsulant delamination-reducing structures 108 on the semiconductor chip 104, which significantly reduces delamination and/or cracking between the encapsulant 106 and the semiconductor chip 104.

The substrate 102 of the semiconductor package 100 may be any type of a substrate on which the semiconductor chip 104 can be mounted. As an example, the substrate 102 can be a leadframe, a printed circuit board (PCB), a ceramic substrate or an injection molded plastic substrate of a molded interconnect device (MID). The semiconductor chip 104 is mounted on an upper surface 110 of the substrate 102. Thus, the semiconductor chip 104 is positioned over the upper surface 110 of the substrate 102. The semiconductor chip 104 can be mounted on the substrate 102 using any mounting technique. The semiconductor chip 104 can be any semiconductor chip or die, such as a light emitting diode (LED) die or a laser diode die. The semiconductor chip 104 can also be any integrated circuit (IC) chip or die, which may include one or more optoelectronic components such as photosensors, image sensors, interpolator ICs, etc. As shown in FIG. 1, the semiconductor chip 104 includes an upper major surface 112, which faces away from the upper surface 110 of the substrate 102.

In this embodiment, the semiconductor package 100 includes only a single semiconductor chip mounted on the substrate 102 and encapsulated by the encapsulant 106. However, in other embodiments, the semiconductor package 100 may include multiple semiconductor chips.

The encapsulant 106 of the semiconductor package 100 can be made of any substance that can be used to encapsulate the semiconductor chip 104. In this embodiment, the encapsulant 106 is made of an optically transparent material so that the semiconductor chip 104 may transmit and/or receive optical signals. As an example, the encapsulant 106 may be made of an optically transparent plastic material or other material commonly used in molded IC packages. However, in other embodiments, the encapsulant 106 can be made of any encapsulating material, which may not necessary be optically transparent.

The encapsulant delamination-reducing structures 108 of the semiconductor package 100 are attached to the upper major surface 112 of the semiconductor chip 104. Thus, the encapsulant delamination-reducing structures 108 are positioned at an interface between the encapsulant 106 and the semiconductor chip 104. Thus, each encapsulant delamination-reducing structure 108 is a structural interface between the encapsulant 106 and the semiconductor chip 104. The encapsulant delamination-reducing structures 108 enhance the mechanical interlocking of the encapsulant 106 on the upper major surface 112 of the semiconductor chip 104. Furthermore, the encapsulant delamination-reducing structures 108 absorb the stress due to expansion of the encapsulant 106, which reduces the risk of delamination and/or cracking between the semiconductor chip 104 and the encapsulant 106.

In this embodiment, the encapsulant delamination-reducing structures 108 are dummy studs formed on the upper major surface 112 of the semiconductor chip 104. The dummy studs 108 are formed on wirebond pads (not shown) on the upper major surface 112 of the semiconductor chip 104. In this embodiment, the dummy studs 108 are made of gold or copper. Gold studs are commonly used in flip chip technology, and sometimes referred to as gold stud bumps. Thus, the dummy studs 108 can be considered to be dummy stud bumps. However, in other embodiments, the dummy studs 108 can be made of any material that can be used to form the dummy studs on the upper major surface 112 of the semiconductor chip 104. The dummy studs 108 can be formed on the upper major surface 112 of the semiconductor chip 104 using a conventional wirebonding machine.

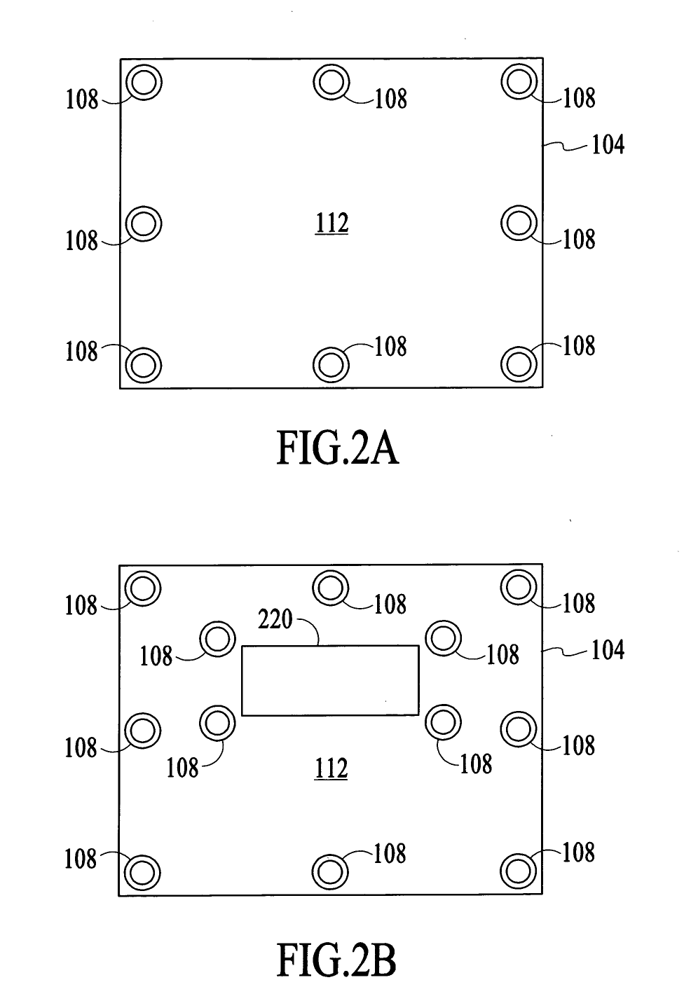

The dummy studs 108 can be strategically positioned on the upper major surface 112 of the semiconductor chip 104 to reduce or eliminate encapsulant delamination and/or cracking, especially during solder reflow when the semiconductor package 100 is subjected to thermal and moisture expansion. As an example, in FIG. 2A, the dummy studs 108 may be arranged to be positioned at or near the corners of the semiconductor chip 104 on the upper major surface 112 of the semiconductor chip. Thus, one of the dummy studs 108 is positioned at or near each corner of the semiconductor chip 104. The dummy studs 108 may also be arranged to be positioned along the edges of the semiconductor chip 104 on the upper major surface 112 of the semiconductor chip. As another example, in FIG. 2B, additional dummy studs 108 are positioned near a critical area of the semiconductor chip 104, which in this example is a photosensor 220 of the semiconductor chip 104. The number of dummy studs 108 formed on the semiconductor chip 104 at least depends on the size of the semiconductor chip. If the semiconductor chip 104 is large, then more dummy studs 108 may be formed on the semiconductor chip to ensure that the possibility of encapsulant delamination and/or cracking is sufficiently reduced.

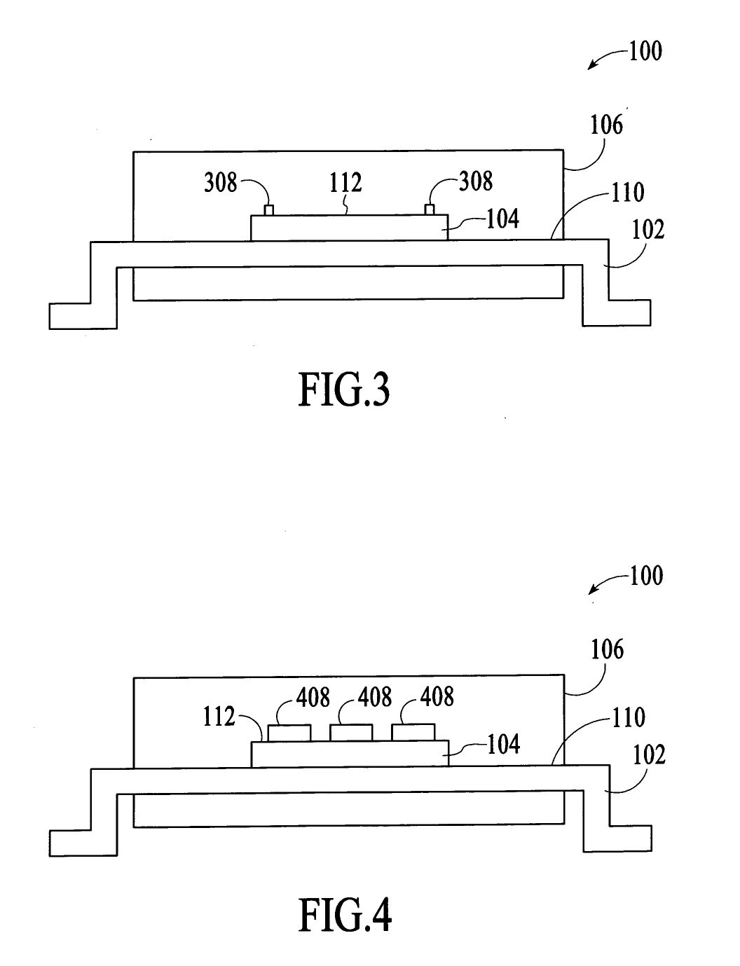

In another embodiment, as illustrated in FIG. 3, the semiconductor package 100 includes encapsulant delamination-reducing structures in the form of dummy pillars 308 formed on the upper major surface 112 of the semiconductor chip 104. Similar to the dummy studs 108, the dummy pillars 308 are formed on wirebond pads (not shown) on the upper major surface 112 of the semiconductor chip 104. In this embodiment, the dummy pillars 308 are made of copper or gold. Copper pillars are commonly used in flip chip technology, and sometimes referred to as pillar bumps. Thus, the dummy pillars 308 can be considered to be dummy pillar bumps. However, in other embodiments, the dummy pillars 308 can be made of any material that can be used to form the dummy pillars on the upper surface 112 of the semiconductor chip 104. The dummy pillars 308 can be formed on the semiconductor chip 104 using a known semiconductor process involving photoresist and electroplating, which is commonly known as wafer bumping.

The dummy pillars 308 can also be strategically positioned on the upper major surface 112 of the semiconductor chip 104 to reduce the possibility of encapsulant delamination and/or cracking. The dummy pillars 308 can be placed at or near corners and edges of the semiconductor chip 104 in a similar arrangement as the dummy studs 108 shown in FIG. 2A. The dummy pillars 308 can also be placed near a critical area of the semiconductor chip 104, such as the photosensor 220, in a similar arrangement as the dummy studs 108 shown in FIG. 2B.

In another embodiment, as illustrated in FIG. 4, the semiconductor package 100 includes encapsulant delamination-reducing structures in the form of dummy blocks 408 attached to the upper major surface 112 of the semiconductor chip 104. The dummy blocks 408 can be made of dummy semiconductor chips, ceramic substrates, metal substrates or blocks of plastic or glass. In fact, the dummy blocks 408 can be made of any material that can withstand the reflow temperature. The dummy blocks 408 can be attached to the upper major surface 112 of the semiconductor chip 104 using adhesives. In an embodiment, one or more exposed surfaces of the dummy blocks 408 may be roughened surfaces to increase their adhesive bond to the encapsulant 106. These exposed surfaces of the dummy blocks 408 may be roughened by chemical etching or sand blasting. In another embodiment, one or more exposed surfaces of the dummy blocks 408 may be perforated surfaces to increase their adhesive bond to the encapsulant 106. These exposed surfaces of the dummy blocks 408 may be perforated by drilling into the surfaces of the dummy blocks. In the illustrated embodiment, the dummy blocks 408 are rectangular in shape. However, in other embodiments, the dummy blocks 408 may have a different shape.

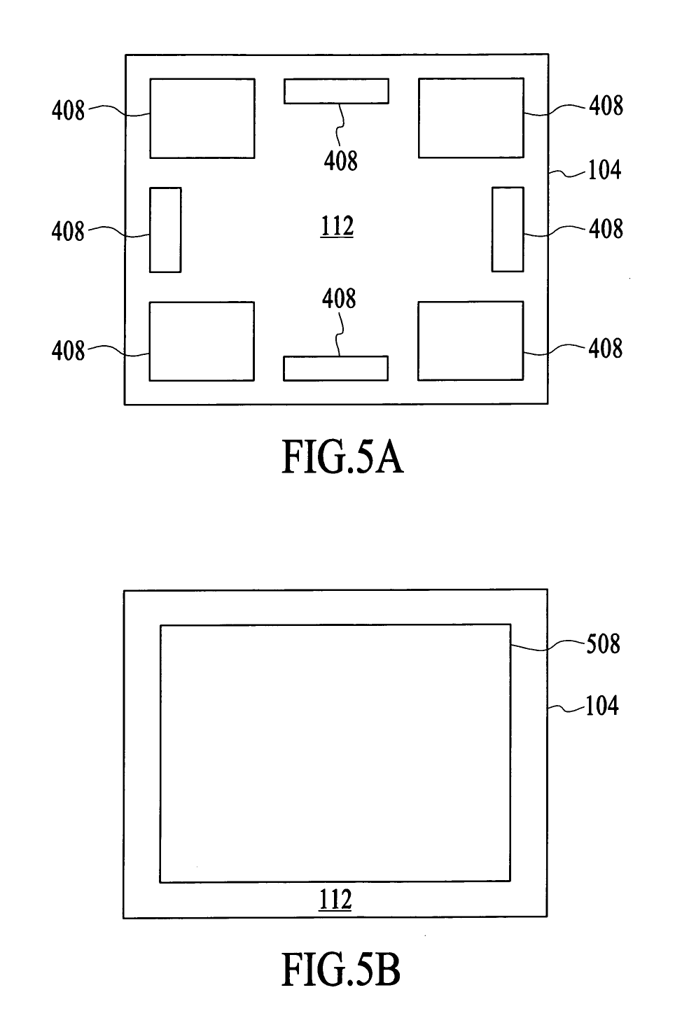

Similar to the dummy studs 108 and pillars 308, the dummy blocks 408 can also be strategically arranged on the upper major surface 112 of the semiconductor chip 104 to reduce the possibility of encapsulant delamination and/or cracking. As illustrated in FIG. 5A, the dummy blocks 408 can be placed at or near corners and edges of the semiconductor chip 104. As shown in FIG. 5A, the dummy blocks 408 can be blocks of different sizes. In the illustrated example, the dummy blocks 408 positioned at or near the corners of the semiconductor chip 104 are larger than the other dummy blocks, which are positioned near the edges of the semiconductor chip between the corners of the semiconductor chip. However, in other embodiments, the dummy blocks 408 can be arranged such that smaller blocks are positioned at or near the corners of the semiconductor chip 104. Alternatively, all the dummy blocks 408 may be same sized blocks. Although not illustrated, the dummy blocks 408 can also be placed near a critical area of the semiconductor chip 104, such as the photosensor 220, in a manner similar to the dummy studs 108 shown in FIG. 2B.

In an embodiment, the semiconductor package 100 may include only a single large dummy block 508, as illustrated in FIG. 5B. The single dummy block 508 is attached to the upper major surface 112 of the semiconductor chip 104. The single dummy block 508 may be centered on the upper major surface 112 of the semiconductor chip 104. In this embodiment, the single dummy block 508 may be made of an optically transparent material, such as plastic or glass, so that the dummy block does not optically interfere with any optoelectronic component included in the semiconductor chip 104.

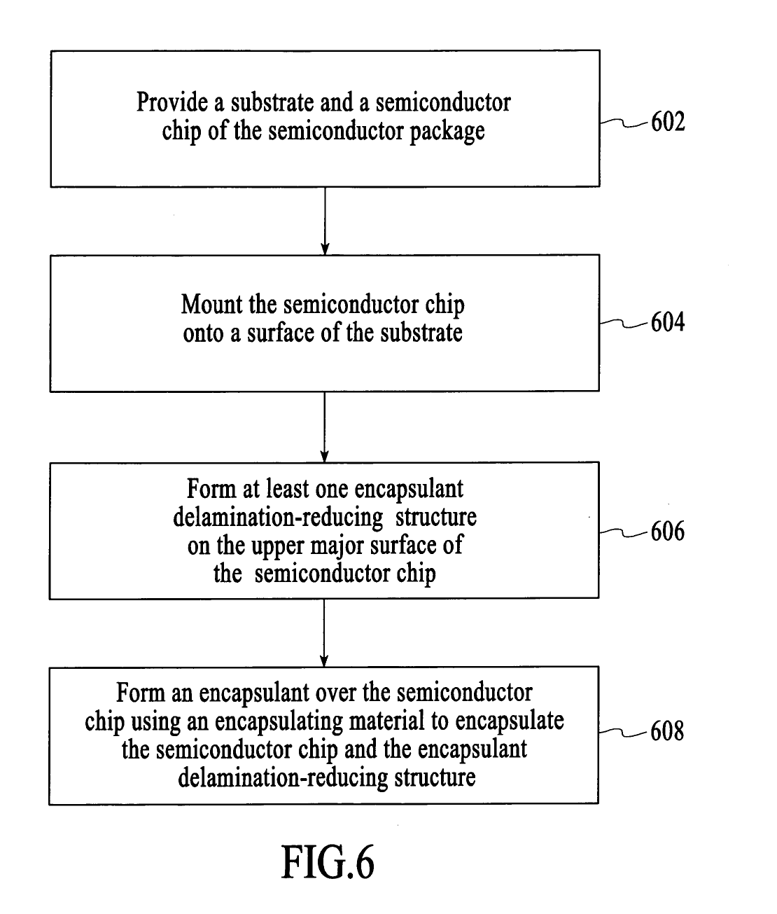

A method of making a semiconductor package in accordance with an embodiment of the invention is described with reference to a process flow diagram of FIG. 6. At block 602, a substrate and a semiconductor chip of the semiconductor package are provided. Next, at block 604, the semiconductor chip is mounted onto a surface of the substrate. The semiconductor chip is mounted such that an upper major surface of the semiconductor chip faces away from the substrate surface. Next, at block 606, at least one encapsulant delamination-reducing structure is formed on the upper major surface of the semiconductor chip. The encapsulant delamination-reducing structure may be a dummy stud, a dummy pillar or a dummy block. In an alternative embodiment, the encapsulant delamination-reducing structure is formed on the upper major surface of the semiconductor chip before the semiconductor chip is mounted onto the substrate. Next, at block 608, an encapsulant is formed over the semiconductor chip using an encapsulating material to encapsulate the semiconductor chip and the encapsulant delamination-reducing structure. The encapsulant delamination-reducing structure provides a structural interface between the semiconductor chip and encapsulant.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A semiconductor package comprising:
a substrate having a surface;
a semiconductor chip positioned over said surface of said substrate, said semiconductor chip having an upper major surface that faces away from said surface of said substrate;
an encapsulant positioned to encapsulate said semiconductor chip; and
at least one encapsulant delamination-reducing structure positioned on said upper major surface of said semiconductor chip to provide a structural interface between said semiconductor chip and said encapsulant.

2. The package of claim 1 wherein said at least one encapsulant delamination-reducing structure includes at least one dummy stud formed on said upper major surface of said semiconductor chip.

3. The package of claim 2 wherein said at least one dummy stud is made of gold or copper.

4. The package of claim 1 wherein said at least one encapsulant delamination-reducing structure includes at least one dummy pillar formed on said upper major surface of said semiconductor chip.

5. The package of claim 4 wherein said at least one dummy pillar is made of copper.

6. The package of claim 1 wherein said at least one encapsulant delamination-reducing structure includes at least one dummy block attached to said upper major surface of said semiconductor chip.

7. The package of claim 6 wherein said at least one dummy block is made of a material selected a group consisting of semiconductor material, ceramic material, metal, plastic and glass.

8. The package of claim 6 wherein said at least one dummy block is made of an optically transparent material.

9. The package of claim 6 wherein said at least one dummy block includes a roughened or perforated surface.

10. The package of claim 1 wherein said at least one encapsulant delamination-reducing structure includes a plurality of encapsulant delamination-reducing structures that are positioned at or near each corner of said semiconductor chip on said upper major surface.

11. A method of making a semiconductor package, said method comprising:
providing a substrate and a semiconductor chip of said semiconductor package;
mounting said semiconductor chip onto a surface of said substrate such that an upper major surface of said semiconductor, chip faces away from said surface of said substrate;
forming at least one encapsulant delamination-reducing structure on said upper major surface of said semiconductor chip; and
forming an encapsulant over said semiconductor chip using an encapsulating material to encapsulate said semiconductor chip and said at least one encapsulant delamination-reducing structure, said at least one encapsulant delamination-reducing structure providing a structural interface between said semiconductor chip and encapsulant.

12. The method of claim 11 wherein said forming said at least one encapsulant delamination-reducing structure includes forming at least one dummy stud on said upper major surface of said semiconductor chip.

13. The method of claim 12 wherein said at least one dummy stud is made of gold or copper.

14. The method of claim 11 wherein said forming said at least one encapsulant delamination-reducing structure includes forming at least one dummy pillar on said upper major surface of said semiconductor chip.

15. The method of claim 14 wherein said at least one dummy pillar is made of copper.

16. The method of claim 11 wherein said forming said at least one encapsulant delamination-reducing structure includes attaching at least one dummy block to said upper major surface of said semiconductor chip.

17. The method of claim 16 wherein said at least one dummy block is made of a material selected a group consisting of semiconductor material, ceramic material, metal, plastic and glass.

18. The method of claim 16 wherein said at least one dummy block is made of an optically transparent material.

19. The method of claim 16 wherein said at least one dummy block includes a roughened or perforated surface.

20. The method of claim 11 wherein said forming said at least one encapsulant delamination-reducing structure includes forming a plurality of encapsulant delamination-reducing structures that are positioned at or near each corner of said semiconductor chip on said upper major surface.
